(19) United States
(12) Patent Application Publication
(10) Pub. No.: US 2025/0219527 A1
(43) Pub. Date: Jul. 3, 2025

(54) BUCK CIRCUIT AND CHARGING CONTROLLER AND METHOD USED IN BUCK CIRCUIT

(71) Applicant: NUVOTON TECHNOLOGY CORPORATION, HSINCHU CITY (TW)

(72) Inventor: Yu-Chi CHANG, Zhubei City (TW)

(21) Appl. No.: 18/811,107

(22) Filed: Aug. 21, 2024

(30) Foreign Application Priority Data
Dec. 27, 2023 (TW) 112151108

(51) Int. Cl. H02M 1/088; H02M 3/158; H03K 17/081

(52) U.S. Cl. CPC H02M 1/088; H02M 3/158; H03K 17/08104; H03K 2217/0081

(57) ABSTRACT

A dual mode power integrated circuit and power converter circuit using the same are disclosed. The power integrated circuit can be used for driving a power converter with high side PMOSFET or NMOSFET, wherein the power integrated circuit includes a high side switch driver circuit which is disposed on the isolated area and a high side power provider circuit is also disposed on the isolated area. When the PMOSFET is adopted on the high side, the source terminal voltage of the PMOSFET is input to the high side power provider circuit for generating the operation voltage of the high side switch driver circuit. When the NMOSFET is adopted on the high side, the bootstrap circuit is adopted.

### CROSS-REFFERENCE TO RELATED APPLICATION

THIS APPLICATION CLAIMS THE PRIORITY FROM THE TW patent application No. 112151108, FILED ON Dec. 27, 2023, AND ALL CONTENTS OF SUCH TW PATENT APPLICATION ARE COMPRISED IN THE PRESENT DISCLOSURE.

### BACKGROUND

### 1. Field of the Invention

The present invention relates to technology associated with power electronics, and more particularly, to a power driving integrated circuit which can be used in two high-side switch driving modes and a power conversion circuit using the same.

### 2. Description of the Related Art

In the design of a power supply circuit or motor driving circuit, the use of multiple switching elements is inevitable. More particularly, in applications requiring high efficiency and complex operations, the high-side N-type switching elements are often used, which has advantages in some specific application scenarios. However, due to the bottleneck of current technologies, the driving circuits are usually specifically designed for these N-type switching elements to ensure the correct and reliable operations.

A common challenge in design is to consider the gate driving issues when the high-side N-type switching elements are used. The gate of the high-side N-type switching element needs a high voltage potential to ensure the correct enabling and shut down. In order to solve this problem, engineers usually use a bootstrap circuit. The bootstrap circuit can increase the gate voltage by charging the internal capacitor to ensure the correct operation of the N-type switching element. This is a very effective and has been widely applied, especially in high-voltage and high-efficiency systems.

On the other hand, even if the high-side switching element is a P-type switching element, similar challenges are taken into consideration in this application. The withstand voltage between the gate and the source of the P-type switching element is usually relatively low, and the highest voltage so far is merely about 40V. Therefore, when the high-side P-type switching element is turned on, the magnitude of the source voltage must be taken into account for the gate voltage. Therefore, in some applications, engineers need to design an additional gate driving circuit to ensure the correct operation of P-type switching elements.

Therefore, so far there is no single power-driving integrated circuit capable of completely coping with all situations, i.e., driving the high-side N-type switching element and the high-side P-type switching element at the same time. The power-driving integrated circuits provided in the market so far are usually single-functional, and are generally designed for the high-side N-type switching elements. This makes the engineers need to carefully consider the requirements of different parts in the process of designing circuits, and choose the appropriate power supply to drive integrated circuits to meet these requirements.

### SUMMARY

The invention provides a dual-mode power-driving integrated circuit and a power conversion circuit using the same, which are configured to drive the N-type/P-type high-side switching elements using the same power-driving integrated circuit, so that customers do not need to switch to other integrated circuits simply because the N-type/P-type high-side switching element is changed to P-type/N-type instead.

An embodiment of the present invention provides a power-driving integrated circuit. The power driving integrated circuit can be configured to drive high-side N-type Metal-Oxide-Semiconductor Field-Effect Transistor (NMOSFET and high-side P-type Metal-Oxide-Semiconductor Field-Effect Transistor (PMOSFET), wherein the power driving integrated circuit comprises a high-side power pin, a high-side floating common pin, a high-side driving pin, a switching control circuit, a low-side switch driving circuit, a high-side switch driving circuit and a high-side power supply circuit.

The switching control circuit receives an integrated circuit power voltage and an integrated circuit common voltage as operating voltages, wherein the switching control circuit is arranged in a first area. The low-side switch driving circuit receives the integrated circuit power voltage and the integrated circuit common voltage as operating voltages and is coupled with the switching control circuit so that the low-side MOSFET is controlled by the switching control circuit. The low-side switch driving circuit is arranged in the first area. The high-side switch driving circuit is coupled to the switching control circuit, and is configured to output a high-side control signal to the high-side driving pin so that a high-side MOSFET is controlled by the switching control circuit, wherein the high-side switch driving circuit is arranged in a second region. The second region comprises an isolation layer to isolate the common voltage of the integrated circuit in the first region, and the high-side switch driving circuit has a high-side power node and a high-side floating common node. The high-side power supply circuit is coupled to the high-side power supply pin and the high-side floating common pin to generate a high-side power voltage and a high-side common voltage, which are respectively provided to the high-side power node and the high-side floating common node.

To sum up, the embodiment of the present invention has a high-side switch driving circuit arranged in the isolated area in the power driving integrated circuit, and an independent high-side power supply circuit is also arranged in the isolated area. When a P-type transistor is arranged on the high side, the input voltage of the P-type source is input to the high-side power supply circuit to generate the operating voltage required by the high-side switch driving circuit. When the high side is equipped with an N-type transistor, it is driven by a bootstrap circuit, so that the invention can be used for driving the high-side N-type transistor and the high-side P-type transistor at the same time.

In order to further understand the technology, means and effects of the present invention, reference can be made to the following detailed description and drawings, so that the objects, features and concepts of the present invention can be thoroughly and concretely understood. However, the following detailed description and drawings are only for reference and explanation of the implementation of the present invention, rather than limiting the scope of the present invention.

### BRIEF DESCRIPTION OF THE DRAWINGS

The accompanying drawings are provided for further understanding of the invention by those who have ordinary knowledge in the technical field to which the invention belongs, and are incorporated into and constitute a part of the specification of the invention. The accompanying drawings illustrate exemplary embodiments of the invention and together with the description of the invention serve to explain the principles of the invention.

FIG. 1 shows a circuit diagram of a power-driving integrated circuit according to a preferred embodiment of the present invention.

FIG. 2 shows another circuit diagram of a power-driving integrated circuit according to a preferred embodiment of the present invention.

FIG. 3 shows a circuit diagram of the high-side power supply circuit of the power-driving integrated circuit according to a preferred embodiment of the present invention.

FIG. 4 shows a circuit diagram of the high-side power supply circuit of the power-driving integrated circuit according to another preferred embodiment of the present invention.

### DESCRIPTION OF THE PREFERRED EMBODIMENTS

Reference will now be made in detail to exemplary embodiments and illustrated in the accompanying drawings of the present invention. In most circumstances, the same symbol used in the drawings and the description refers to the same or similar parts. In addition, the practice of the exemplary embodiment is only one of the implementations of the design concept of the present invention, and the following demonstrations are not meant to limit the scope of the present invention.

In the following embodiments, a power conversion circuit using a dual-mode power supply to drive an integrated circuit is proposed. In the following embodiments, a high-side MOSFET and a low-side MOSFET are illustrated as examples. Those skilled in the art should know that the number of MOSFETs may increase according to different applications. For example, the full-bridge topology includes two high-side power MOSFETs and two low-side power MOSFETs, and the three-phase six-step DC motor driving includes three high-side power MOSFETs and three low-side power MOSFETs. Details about the above elements are omitted here for brevity.

In general, no matter the high-side is PMOSFET or NMOSFET, to drive the high-side MOSFET M1 in an integrated circuit requires special circuit design. In this embodiment, the dual-mode power-driving integrated circuit 101 can be configured to drive MOSFETs whose high side is P-type or N-type. In order to explain how to drive the high-side PMOSFET and high-side NMOSFET at the same time, more detailed examples are shown below.

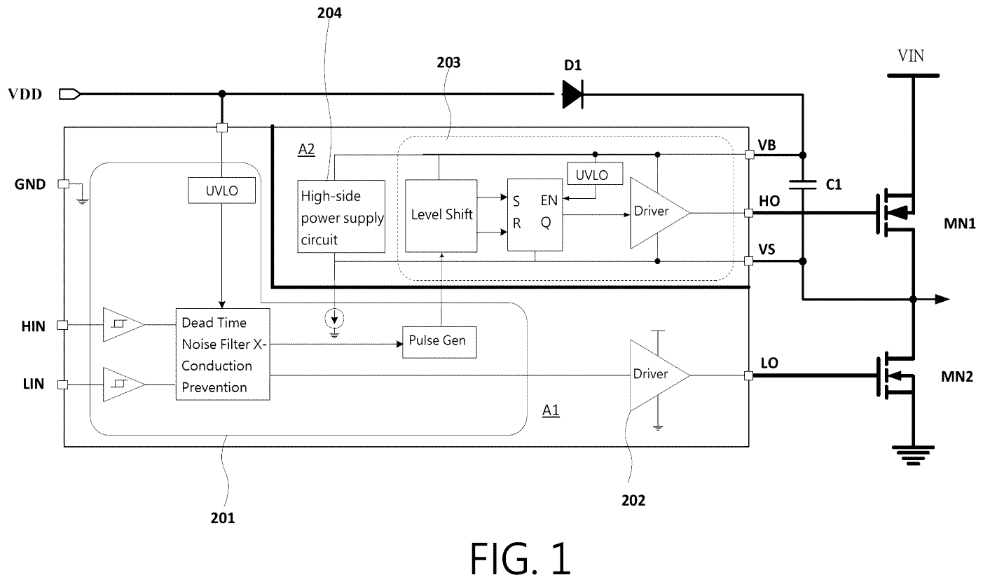

FIG. 1 shows a circuit diagram of a dual-mode power-driving integrated circuit 101 according to a preferred embodiment of the present invention. Please refer to FIG. 1, in this embodiment, the dual-mode power driving integrated circuit 101 includes a switching control circuit 201, a low-side switch driving circuit 202, a high-side switch driving circuit 203 and a high-side power supply circuit 204. In addition, the power-driving integrated circuit 101 may be divided into two regions, e.g., a first region A1 and a second region A2. The circuits in the first region A1 operate using the integrated circuit power voltage VDD and the integrated circuit common voltage GND as operating voltages. There is an isolation layer between the second region A2 and the first region A1 to isolate the integrated circuit power voltage VDD and the integrated circuit common voltage VGND of the first region A1.

The switching control circuit 201 is configured to control the switching of the low-side switch driving circuit 202 and the high-side switch driving circuit 203 according to the feedback. The low-side switch driving circuit 202 is controlled by the switching control circuit 201 to control the low-side MOSFET M1 through the lower driving pin LO. The switching control circuit 201 and the low-side switch driving circuit 202 are both arranged in the first area A1.

The high-side switch driving circuit 203 is coupled to the switching control circuit 201, and is configured to refer to the control pulses of the switching control circuit 201 to output a high-side control signal to the high-side MOSFET M2 through the high-side driving pin HO by using a voltage level converter and an output amplifier, for example. The high-side switch driving circuit 203 has three pins connected to external circuits, i.e., a high-side power pin VB, a high-side floating common pin VS and a high-side driving pin HO.

In addition, in the example of this embodiment, the high-side switch driving circuit 203 drives the high-side NMOSFET MN1. Therefore, the high-side power supply pin VB corresponding to the high-side switch driving circuit 203 is electrically connected to the cathode of the external rectifier diode D1, and the anode of the external rectifier diode D1 is electrically connected to the integrated circuit power voltage VDD. In addition, a rectifying capacitor C1 is electrically connected between the high-side power supply pin VB and the high-side floating common pin VS corresponding to the high-side switch driving circuit 203. The high-side floating common pin VS corresponding to the side switch driving circuit 203 is also electrically connected to the source of the high-side NMOSFET M1.

As long as the gate-to-source voltage VGS is less than the threshold voltage VT, the switching control circuit 201 may be configured to control the high-side NMOSFET MN1 to turn off. The details are omitted here for brevity. However, when the high-side NMOSFET MN1 is turned off, the source voltage approximates to 0V, and thus the voltage at both ends of the rectifying capacitor C1 is charged to the integrated circuit power voltage VDD. When the switching control circuit 201 controls the high-side NMOSFET MN1 to be turned on, the high-side switch driving circuit 203 receives the control signal of the switching control circuit 201 through the internal voltage level converter, and outputs the high-side control signal to the high-side driving pin HO through the internal output amplifier. In this moment, after the high-side NMOSFET MN1 is turned on, the input voltage VIN of the drain of the high-side NMOSFET MN1 is input into the source of the high-side NMOSFET MN1, and the rectifier capacitor C1 is coupled to the node of the source, i.e., the high-side floating common pin bit VS also receives the input voltage VIN of 200V, making the operating voltage of the high-side switch driving circuit 203 be substantially set between 200V+VDD and 200V, so that the high-side control signal (i.e., the gate voltage) output by the high-side driving pin HO is substantially equal to 200V+VDD. As a result, the high-side NMOSFET MN1 can be completely turned on.

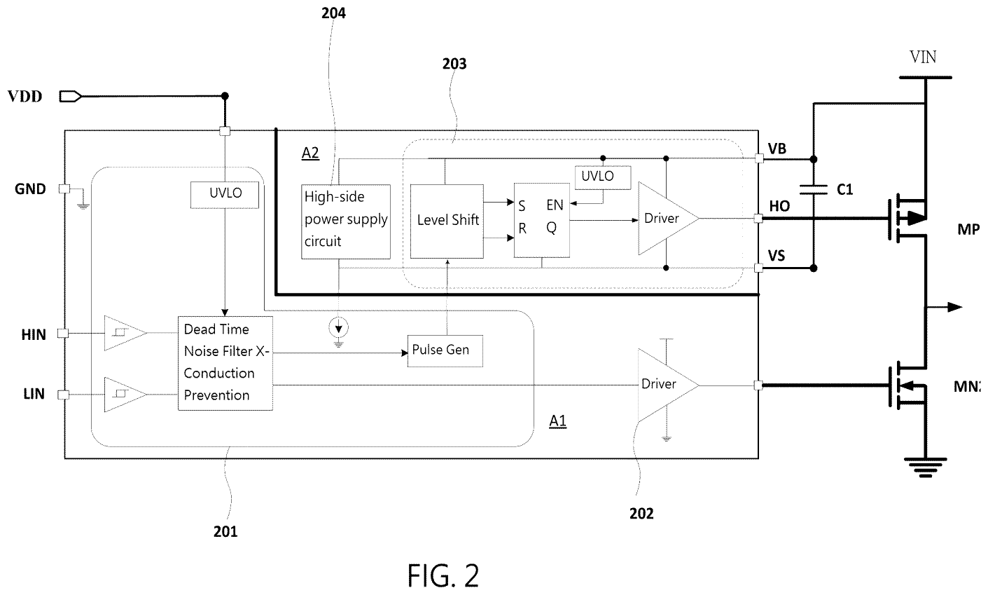

FIG. 2 shows a circuit diagram of a dual-mode power-driving integrated circuit 101 according to a preferred embodiment of the present invention. Please refer to FIG. 2. The difference between this embodiment and the embodiment of FIG. 1 is that the high-side NMOSFET MN1 is replaced by the high-side PMOSFET MP1. Since the high-side is changed to the PMOSFET MP1, the external rectifying diode D1 is removed, and the node of the rectifying capacitor C1 electrically connected to the high-side power supply pin VB is electrically connected to the source of the high-side PMOSFET MP1, i.e., the input voltage VIN. In addition, a difference in the embodiment of FIG. 2 is that the high-side floating common pin VS is only electrically connected to the other end of the rectifying capacitor C1, and is not electrically connected to any other MOSFET.

When the switching control circuit 201 is arrange to control the high-side PMOSFET MP1 to be turned on, the general consensus only requires the gate-source voltage VGS to be greater than the threshold voltage VT. Hence, given that the high-side input voltage VIN is 200V, the gate will be turned on even if it receives 0V. However, as the voltage withstand of the gate-source voltage of the power transistor is about 40V at most in practice, if 0V directly given, the gate-to source voltage VGS will be equal to 200V, which directly exceeds the withstand voltage of 40V, causing the high-side PMOSFET to burn out.

Therefore, in this embodiment, the high-side power supply circuit 204 will get 200V through the rectifier capacitor C1, and the current-limiting circuit inside the high-side power supply circuit 204 will be coupled to the integrated circuit common voltage VGND to generate an extremely small current, so as to adjust the voltage and obtain the high-side power voltage VBB and the high-side common voltage VSS for the high-side switch driving circuit 203 to operate. In this embodiment, the voltage difference between the high-side power voltage VBB and the high-side common voltage VSS may be 12V. When the high-side power voltage VBB is equal to 200V, the high-side common voltage VSS will be adjusted to 188V. Therefore, when the high-side PMOSFET MP1 is controlled to be turned on, the high-side switch driving circuit 203 may output a voltage of 188V to the high-side driving pin HO, so that the gate voltage of the high-side PMOSFET MP1 can be set at 188V, the gate-source voltage of the high-side PMOSFET MP1 can be maintained at 12V, and the high-side PMOSFET MP1 can be prevented from burning out.

When the switching control circuit 201 wants to control the high-side NMOSFET MP1 to turn off, the high-side power supply circuit 204 provides the high-side power voltage VBB and the high-side common voltage VSS for the high-side switching drive circuit 203 to operate. When the high-side power voltage VBB reaches 200V, the high-side common voltage VSS is adjusted to 188V, Therefore, the operating voltage of the high-side switch driving circuit 203 can be set between 200V and 188V, and the high-side control signal output by the high-side driving pin HO can be set at 200 V. Therefore, the high-side PMOSFET MP1 can be turned off.

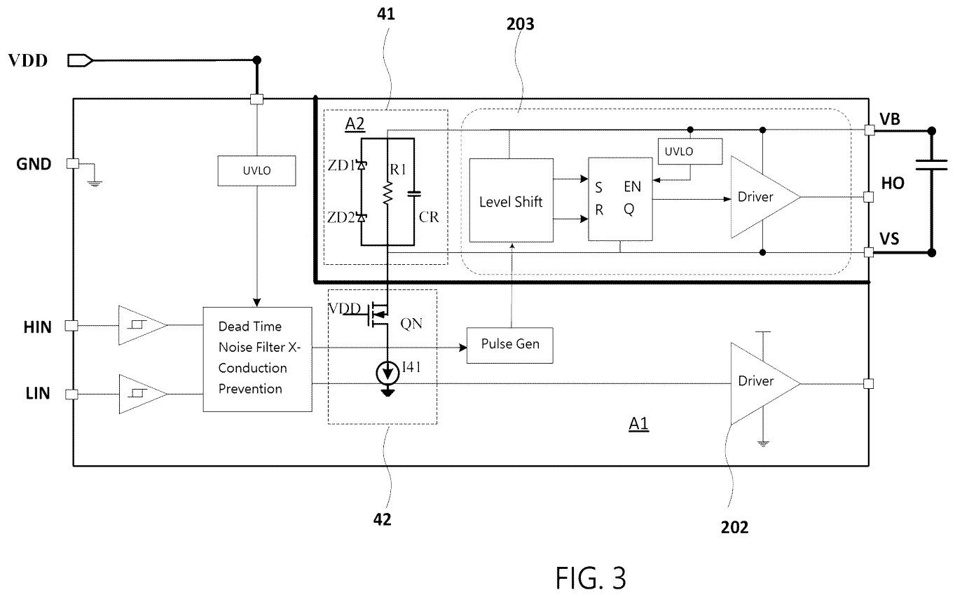

FIG. 3 shows a circuit diagram of the high-side power supply circuit 204 of the dual-mode power-driving integrated circuit 101 according to a preferred embodiment of the present invention. Please refer to FIG. 3. In this embodiment, the high-side power supply circuit 204 includes a voltage-regulating circuit 41 and a current-limiting circuit 42. The current-limiting circuit 42 is coupled between the voltage-regulating circuit 41 and the integrated circuit common voltage VGND in the first area A1. In this embodiment, the current-limiting circuit 42 includes an NMOSFET QN and a micro-current source I41. Also in this embodiment, the voltage-regulating circuit 41 includes a first zener diode ZD1, a second zener diode ZD2, an internal filtering regulating capacitor CR and a first resistor R1.

The cathode of the first zener diode ZD1 is coupled to the high-side power supply pin VB. The cathode of the second zener diode ZD2 is coupled to the anode of the first zener diode ZD1, and the anode of the second zener diode ZD2 is coupled to the high-side floating common pin VS. Two ends of the internal filtering regulating capacitor CR are coupled between the high-side power supply pin VB and the high-side floating common pin VS. Two ends of the first resistor R1 are coupled between the high-side power supply pin VB and the high-side floating common pin VS. The current-limiting circuit 42 is coupled between the anode of the second zener diode ZD2 and the integrated circuit common voltage VGND, and is mainly used as the reference voltage/current of the voltage-regulating circuit 41.

In this embodiment, the first zener diode ZD1 and the second zener diode ZD2 function as the highest voltage limiting elements. The NMOSFET QN is configured to provide the voltage limiting function for protecting the micro-current source I41. As can be seen from the above circuit, the voltage on the internal filtering regulating capacitor CR can be expressed by:

$$V BB - V SS = I 41 * R 1$$

where I41 denotes the current of the micro-current source I41, R1 is denotes as the resistance of the first resistor R1. In this embodiment, for example, I41=12 uA, and R1=1000KΩ, then the voltage across the internal filtering regulating capacitor CR will be (VIN-12V), that is, the voltage difference with VIN will be fixed at 12V. In this way, the voltage between the high-side power supply pin VB and the high-side floating common pin VS may be maintained at 12V in the above embodiment, so that the high-side switch driving circuit 203 can normally operate at an operating voltage, e.g., 200V to 188V, without burning out.

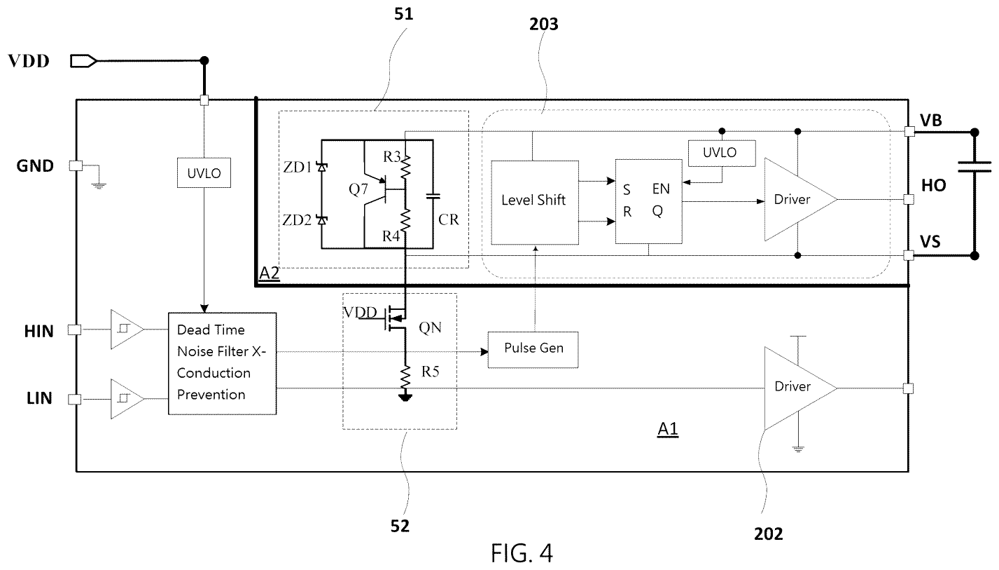

FIG. 4 shows a circuit diagram of the high-side power supply circuit 204 of the dual-mode power-driving integrated circuit 101 according to a preferred embodiment of the present invention. Please refer to FIG. 4. In this embodiment, the high-side power supply circuit 204 also includes a voltage-regulating circuit 51 and a current-limiting circuit 52. The current-limiting circuit 42 is also coupled between the voltage-regulating circuit 41 and the integrated circuit common voltage VGND in the first area A1. In this embodiment, the current-limiting circuit 42 includes an NMOSFET QN and a current-limiting resistor R5. In this embodiment, the voltage-regulating circuit 41 includes a P-type bipolar transistor Q7, a first resistor R3 and a second resistor R4, in addition to the first zener diode ZD1, the second zener diode ZD2 and the internal filtering regulating capacitor CR.

The cathode of the first zener diode ZD1 is coupled to the high-side power supply pin VB. The cathode of the second zener diode ZD2 is coupled to the anode of the first zener diode ZD1, and the anode of the second zener diode ZD2 is coupled to the high-side floating common pin VS. Two ends of the internal filtering regulating capacitor CR are coupled between the high-side power supply pin VB and the high-side floating common pin VS. The emitter of P-type bipolar transistor Q7 is coupled to the high-side power supply pin VB, and the collector of P-type bipolar transistor Q7 is coupled to the high-side floating common pin VS. The first resistor R3 is coupled between the high-side power supply pin VB and the base of the P-type bipolar transistor Q7. The second resistor R4 is coupled between the base of the P-type bipolar transistor Q7 and the high-side floating common pin VS.

In this embodiment, the first zener diode ZD1 and the second zener diode ZD2 are mainly configured to limit the maximum voltage. The current-limiting resistor R5 is used for current-limiting, and the NMOSFET QN is used for voltage limiting protection. In this embodiment, due to the arrangement of P-type bipolar transistor Q7, the voltage across the internal filtering regulating capacitor CR can be expressed as:

$$V BE * ( 1 + R 4 / R 3 )$$

where VBE denotes the base-emitter voltage of P-type bipolar transistor Q7, R4 denotes the resistance of the second resistor R4, and R3 denotes the resistance of the first resistor R3.

Given that VBE=0.6V, R3=100KΩ, R4=1900KΩ, the voltage (VBB-VSS) across the internal filtering regulating capacitor CR will be equal to:

$$0.6 V * 1 + 1900 K / 100 K = 12 V$$

That is, by using the P-type bipolar transistor Q7, the voltage (the voltage difference with VIN) at both ends of the internal filtering regulating capacitor CR is fixed to 12V, thus ensuring that all circuits in the high-side switch driving circuit 203 can operate normally, and the high-side PMOSFET MP1 can also operate normally upon switching.

Although there are only two circuit implementations of the high-side power supply circuit 204 are provided in the above embodiment. However, those skilled in that art should be readily to understand that the above implementation circuits can be implemented in alternative ways after referring to the above detailed circuits. Without changing the spirit of the invention, the invention is not limited to the above-shown embodiments. In addition, as the NMOSFET QN in the above two embodiments has the function of protecting and limiting voltage, these design can be optionally disabled, in actual implementation of the circuit.

To sum up, the embodiment of the present invention provides the design that the high-side switch driving circuit arranged in the isolated area in the dual-mode power driving integrated circuit, and an independent high-side power supply circuit is also arranged in the isolated area. When a P-type transistor is arranged on the high side, the input voltage of the P-type source is input to the high-side power supply circuit to generate the operating voltage required by the high-side switch driving circuit. When the high-side is equipped with an N-type transistor, it is driven by a bootstrap circuit, so that the present invention can be used for driving the high-side N-type transistor and the high-side P-type transistor at the same time.

It should be understood that the examples and embodiments described herein are for illustrative purposes only, and various modifications or changes can be oblivious to those skilled in the art. These modifications or changes shall be also within the scope of the spirit and scope of the present application and are included in the claims.

What is claimed is:

1. A power-driving integrated circuit, comprising:
a switching control circuit, configured to receive an integrated circuit power voltage and an integrated circuit common voltage as operating voltages, wherein the switching control circuit is arranged in a first area;
a low-side switch driving circuit, configured to receive the integrated circuit power voltage and the integrated circuit common voltage as operating voltages, wherein the low-side switch driving circuit is controlled by the switching control circuit to control a low-side Metal-Oxide-Semiconductor Field-Effect Transistor (MOSFET), wherein the low-side switch driving circuit is arranged in the first area;
a high-side power supply pin;
a high-side floating common pin; and
a high-side driving pin;
a high-side switch driving circuit, coupled to the switching control circuit, and controlled by the switching control circuit to output a high-side control signal to the high-side driving pin to control a high-side MOSFET, wherein the high-side switch driving circuit is arranged in a second region, the second region comprises an isolation layer to isolate the integrated circuit common voltage of the first region, and the high-side switch driving circuit has a high-side power node and a high-side floating common node; and
a high-side power supply circuit, coupled to the high-side power supply pin and the high-side floating common pin, and configured to generate a high-side power voltage and a high-side common voltage, which are respectively provided to the high-side power node and the high-side floating common node.

2. The power driving integrated circuit according to claim 1, wherein the high-side power supply circuit comprises:
a voltage-regulating circuit;
a current-limiting circuit coupled between the voltage-regulating circuit and the integrated circuit common voltage,
wherein the voltage-regulating circuit is configured to generate the high-side power voltage and the high-side common voltage based on the voltage of the high-side power supply pin and the current-limiting circuit.

3. The power-driving integrated circuit according to claim 2, wherein the voltage-regulating circuit comprises:
a first zener diode, having an anode and a cathode, wherein the cathode of the first zener diode is coupled to the high-side power supply pin;
a second zener diode, having an anode and a cathode, wherein the cathode of the second zener diode is coupled to the anode of the first zener diode, and the anode of the second zener diode is coupled to the high-side floating common pin;
an internal filtering regulating capacitor, having a first end and a second end, wherein the first end of the internal filtering regulating capacitor is coupled to the cathode of the first zener diode, and the second end of the internal filtering regulating capacitor is coupled to the high-side floating common pin; and
a first resistor, having a first end and a second end, wherein the first end of the first resistor is coupled to the cathode of the first zener diode, and the second end of the first resistor is coupled to the anode of the second zener diode.

4. The power-driving integrated circuit according to claim 2, wherein the voltage-regulating circuit comprises:
a first transistor, comprising a base, an emitter and a collector, wherein the emitter of the first transistor is coupled to the high-side power supply pin;
a first resistor, having a first end and a second end, wherein the first end of the first resistor is coupled to the high-side power pin, and the second end of the first resistor is coupled to the base of the first transistor;
a second resistor, having a first end and a second end, wherein the first end of the second resistor is coupled to the base of the first transistor, and the second end of the second resistor is coupled to the high-side floating common pin; and
an internal filtering regulating capacitor, having a first end and a second end, wherein the first end of the internal filtering regulating capacitor is coupled to the cathode of the first zener diode, and the second end of the internal filtering regulating capacitor is coupled to the high-side floating common pin.

5. The power-driving integrated circuit according to claim 4, wherein the voltage-regulating circuit further comprises:
a first zener diode, having an anode and a cathode, wherein the cathode of the first zener diode is coupled to the high-side power supply pin; and
a second zener diode, having an anode and a cathode, wherein the cathode of the second zener diode is coupled to the anode of the first zener diode, and the anode of the second zener diode is coupled to the high-side floating common pin.

6. The power-driving integrated circuit according to claim 2, wherein the current-limiting circuit comprises:
a first transistor, having a gate, a first source drain and a second source drain, wherein the gate of the first transistor is coupled to the integrated circuit power voltage, and the first source drain of the first transistor is coupled to the high-side floating common pin; and
a micro-current source circuit, having a first end and a second end, wherein the first end of the micro-current source circuit is coupled to the second source and drain of the first transistor, and the second end of the micro-current source circuit is coupled to the integrated circuit common voltage.

7. The power-driving integrated circuit according to claim 6, wherein the micro-current source circuit comprises:
a current-limiting resistor, having a first end and a second end, wherein the first end of the current-limiting resistor is coupled to the second source and drain of the first transistor, and the second end of the current-limiting resistor is coupled to the integrated circuit common voltage.

8. A power conversion circuit for converting an input voltage according to requirements of a load, wherein the power conversion circuit comprises:
the power-driving integrated circuit according to claim 1; and
at least one high-side MOSFET, having a gate coupled to the high-side switch driving circuit of the dual-mode power-driving integrated circuit.

9. The power conversion circuit according to claim 8, wherein when the high-side power MOSFET is a high-side P-type power MOSFET, the source of the high-side P-type power MOSFET is coupled to a high-voltage input voltage, the high-side power pin is coupled to the source of the high-side P-type power MOSFET, and the high-side floating common pin is coupled to the drain of the high-side P-type power MOSFET, wherein the power conversion circuit further comprises:
a first capacitor, having a first end and a second end, wherein the first end of the first capacitor is coupled to the source of the high-side PMOSFET, and the second end of the first capacitor is coupled to the drain of the high-side PMOSFET.
